(19) United States
(12) Patent Application Publication
(10) Pub. No.: US 2025/0240984 A1
(43) Pub. Date: Jul. 24, 2025

(54) Capacitive Charge Storage and Transport Device for Room Temperature applications

(71) Applicant: THE BOARD OF TRUSTEES OF THE LELAND STANFORD JUNIOR UNIVERSITY, Stanford, CA (US)

(72) Inventors: Friedrich B. Prinz, Woodside, CA (US); Settasit Chaikasetsin, Menlo Park, CA (US); Simin Nie, Mountain View, CA (US); Martin M. Winterkorn, Santa Clara, CA (US)

(21) Appl. No.: 18/853,322

(22) PCT Filed: Apr. 11, 2023
(86) PCT No.: PCT/US2023/018172

§ 371 Date: Oct. 1, 2024

Related U.S. Application Data
(60) Provisional application No. 63/329,822, filed on Apr. 11, 2022.

(51) Int. Cl. H10D 1/66; H10D 1/00

(52) U.S. Cl. CPC H10D 1/66; H10D 1/047

(57) ABSTRACT

Anomalously large charge storage, charge release and/or charge transport is provided in room temperature MIS (Metal-Insulator-Semiconductor) capacitive structures. These parameters can be 10× or more (often orders of magnitude more) than what would be expected from the classical capacitance of the structure. This anomalous behavior is attributed to topological states formed in the MIS structure under bias when there are both in-plane and out of plane components of the biasing electric field. One signature of this new physical effect is an inverse dependence of maximum current density on area.

### FIELD OF THE INVENTION

This invention relates to charge storage and transport devices.

### BACKGROUND

Nonclassical electrical effects such as superconductivity, Quantum Hall effect etc. are well known in the art to require cryogenic temperatures, intense magnetic fields, or both. Although there have been various theoretical proposals of possible room temperature nonclassical electrical effects, there are few (if any) experimental demonstrations to date of such effects. Accordingly, it would be an advance in the art to provide room temperature nonclassical electrical effects.

### SUMMARY

We have found experimental evidence of nonclassical behavior of capacitive MIS (Metal/Insulator/Semiconductor) structures. In particular, room temperature charge storage, charge release and current transport in our experimental results can be far higher (i.e., orders of magnitude higher) than what would be expected from the classical capacitance of the MIS structure.

Without being bound by theory, it is presently believed that in these and similar geometries, certain electric and/or magnetic field distributions enable the transformation of conventional electronic charges with random phases into states of matter with a topological phase. The finite element simulation with Maxwell's equations reveals that the polarization of transient electric and/or magnetic fields induces regions of high electron densities that, in turn, might lead to topological surface states. A topological electronic phase is characterized by nontrivial topological invariants and represents a state of matter with unique physical properties. For example, the Maxwell equations, which determine the behavior of traditional charges together with associated electric and magnetic fields, are modified in the presence of topological phases. The occurrence of such phases is suggested by the density functional theory simulation leading to non-trivial topological invariants.

Such topological phases may lead to enhanced charge accumulation, enabling the creation of topological capacitors with higher releasable charge densities when compared to traditional capacitors. Electronic charges get stored and may be retrieved upon voltage reversal. Charges retrieved are substantially higher compared to traditional capacitors. The charge density retrieved from smaller devices is higher compared to the charge density retrieved from larger devices.

Topological phase differences in these capacitors may lead to the formation of supercurrents towards equilibrating the phase difference between anode and cathode. Such supercurrents can significantly exceed 1000 Amp/cm² without any observed sample damage. FEM (Finite Element Method) calculations show that traditional charge transport with observed supercurrent densities would lead to the instant melting of the sample. In contrast, the capacitors of this work can deliver high current density pulses without apparent damage. Moreover, present capacitors show higher current density pulses in smaller devices compared to current pulses from larger ones, contrary to traditional capacitive devices. Traditional capacitive currents scale with the area but not with one over the area, as observed here.

Accordingly, in the remainder of this description, “topological states” are defined phenomenologically such that any capacitive device having room temperature charge storage, charge release and/or current transport at least 10× what would be expected from the corresponding classical capacitance is regarded as having “topological states” that are responsible for these remarkable observations.

Significant advantages are provided. Energy density and power density devices are limited in performance today. The architectures considered herein may enhance both metrics significantly. Josephson like transport is known to occur only at very low temperature. We may have observed super currents at room temperature. Some of our devices exhibit current densities of at least 1000 Amps per cm².

Earlier experimental work by our research group found anomalously high charge storage behavior in devices referred to as “all-electron batteries”. An exemplary reference for this work is U.S. patent application Ser. No. 12/798,102, filed on Mar. 29, 2010. However, the idea of forming topological electron states in room temperature semiconductors using in-plane and out-of-plane electrical bias of a low-dimensional electron gas was not considered in U.S. patent application Ser. No. 12/798,102.

### BRIEF DESCRIPTION OF THE DRAWINGS

FIGS. 1A-C show an exemplary embodiment of the invention.

FIG. 1D schematically shows potential topological phase formation in the device and its characteristic band diagram.

FIGS. 2A-B show another exemplary embodiment.

FIG. 3 shows current cycling results over several voltage ranges.

FIGS. 4A-C show an observed violation of classical current continuity.

FIGS. 5A-B show an example of anomalous current transport.

FIGS. 6A-D show current cycling results with and without time delays.

FIG. 7 shows an unexpected inverse scaling of maximum current density with device area.

### DETAILED DESCRIPTION

### I) Introduction

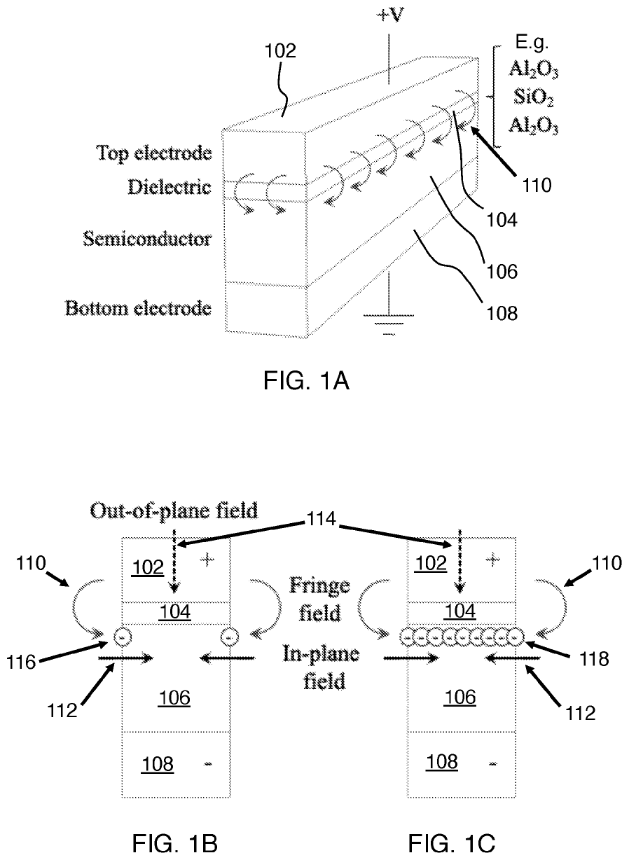

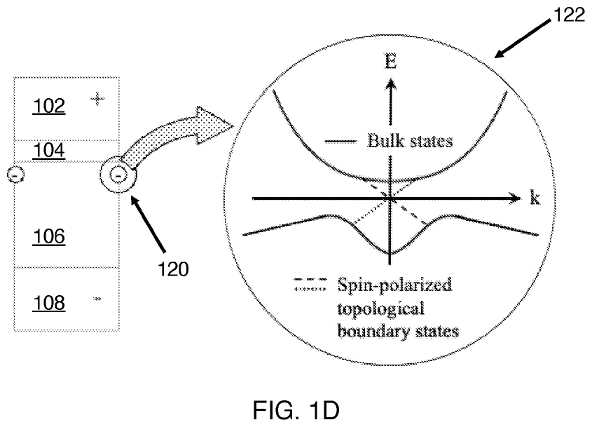

FIG. 1 shows an exemplary capacitive device including a high mobility semiconductor 106 and high breakdown strength dielectric 104 made into a slab shape and sandwiched between top electrode 102 and bottom electrode 108. For example, dielectric 104 can be a three-layer alumina/silica/alumina composite. FIGS. 1B-C are cross-sectional views of this device showing two components of applied electric fields: an out-of-plane component 114 and an in-plane component 112, which can both come from the fringe field 110, potentially inducing 1D electron surface states 116 as on FIG. 1B, or a 2D electron gas 118 as on FIG. 1B. Note that fringe fields are typically regarded as parasitics that would not be present in ideal devices, so this importance of fringe fields is an unexpected feature of this work. Standard cleanroom processing techniques can be used to fabricate the insulator, semiconductor and electrodes of the structures considered herein.

We have unexpectedly found that devices as in the example of FIGS. 1A-C can exhibit the characteristics of quantum charge storage and quantum charge transport at room temperature. The applied electric fields have both out-of-plane and in-plane components (114 and 112, respectively) inducing electronic boundary states, as shown in FIG. 1B and FIG. 1C. A portion of the injected electrons transforms into a topological phase in the form of 1D electron surface states or 2D electron gas states. The present structure differs from devices that show Integer Quantum Hall (IQH) behavior. Low temperatures and strong magnetic fields are needed to achieve IQH phenomena. In contrast, the present device operates at room temperature and induces 1D or 2D electronic gases with applied electric fields only. The resulting unique states may be driven into topological states as indicated in FIG. 1D, or chargeless Majorana phase. More specifically, 120 on FIG. 1D is a schematic representation of a topological state, and 122 on FIG. 1D is a corresponding schematic energy-momentum energy band diagram.

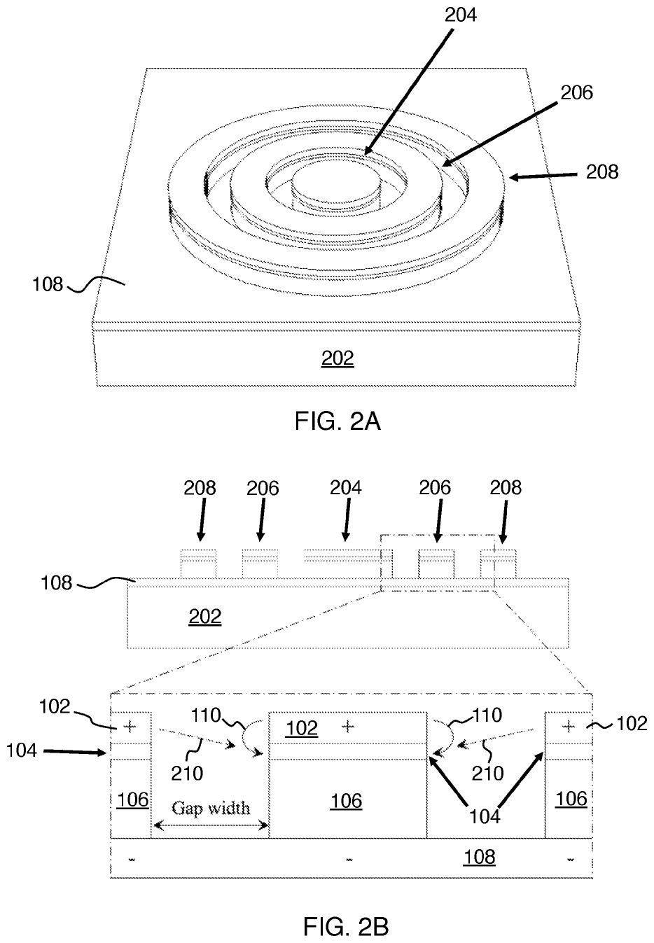

Another geometrical configuration is shown on FIGS. 2A-B, and includes multiple rings around an island to help promote topological state formation in the middle ring 206 due to the neighboring fringe fields from nearby structures (e.g., island 204, outer ring 208). More specifically, FIGS. 2A-B show an exemplary micro capacitor architecture having rings around an island geometry which exhibits high charge accumulation capacity. Here bottom electrode 108 is an unpatterned layer disposed on substrate 202, and the rest of the device is patterned in concentric rings as shown. An island 204 is surrounded by a middle ring 206, which in turn is surrounded by an outer ring 208. As schematically shown on the cross-sectional view of FIG. 2B, the electric and/or magnetic fringe field 210 from the nearby island 204 and outer ring 208 may help promote the formation of topological electron states in the middle ring 206, in addition to any such effect provided by fringing field 110 of the middle ring 206. Note that fringe fields are typically regarded as parasitics that would not be present in ideal devices, so this importance of fringe fields is an unexpected feature of this work.

### II) Non-Classical Electrical Behavior

Non-classical charge transport is experimentally demonstrated by a linear voltage sweep measurement in the out-of-plane direction between the device's top and bottom electrodes (e.g., 102 and 108 on FIGS. 1A-2B). In an in-situ scanning electron microscopy (SEM) measurement, we linearly swept the bias voltage between electrodes 102 and 108 in a cycle starting from 5 V and gradually increased the maximum voltage to 30 V.

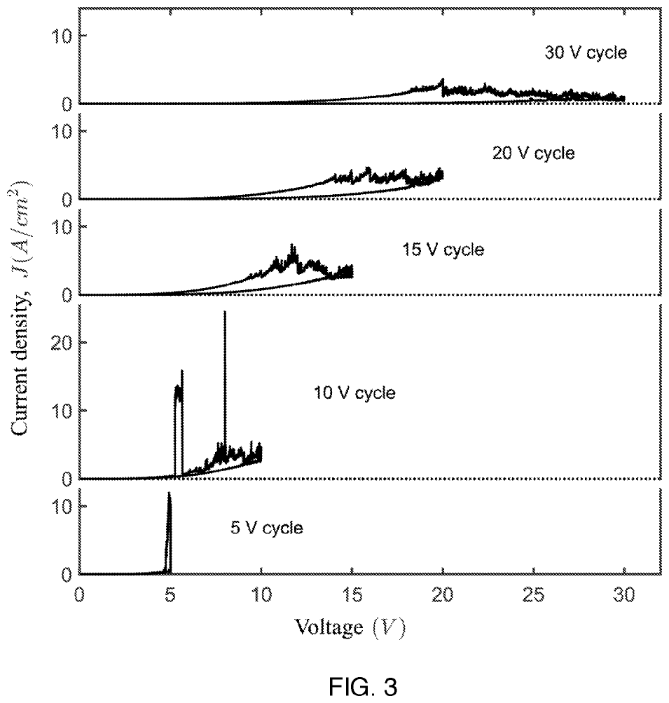

FIG. 3 shows measured current density-voltage characteristics of the capacitive device under a series of linear voltage sweeps from 5 V cycle (sweep from 0 to 5 V and back to 0 V) with subsequent increments up to 30 V cycle showing the following nonclassical characteristics: 1) higher current density than geometric capacitive or leakage currents, 2) high current peak at low voltage, 3) current peak drops at higher voltage cycle, 4) the current density-voltage trend traces the preceding cycle showing a memory effect.

### III) Charge Accumulation Leading to Partial Lossless Charge Transport

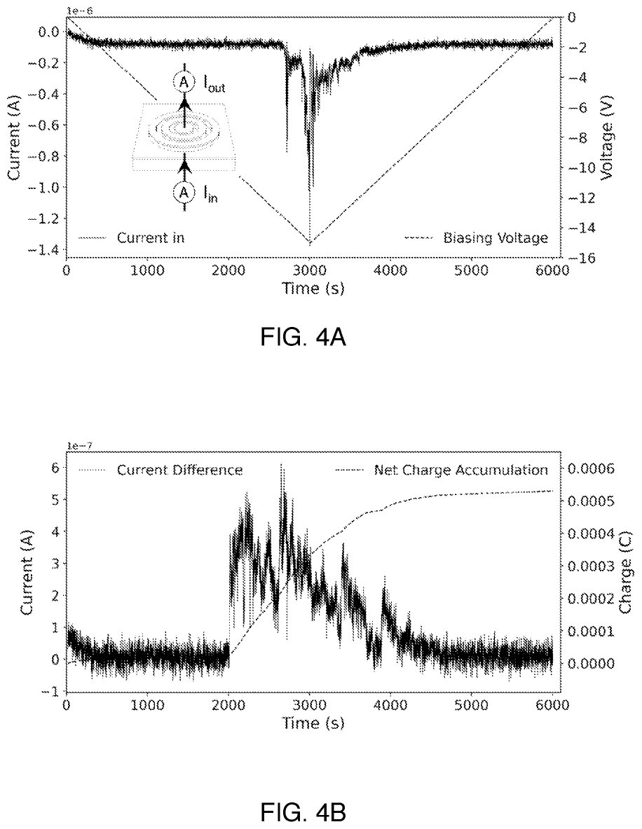

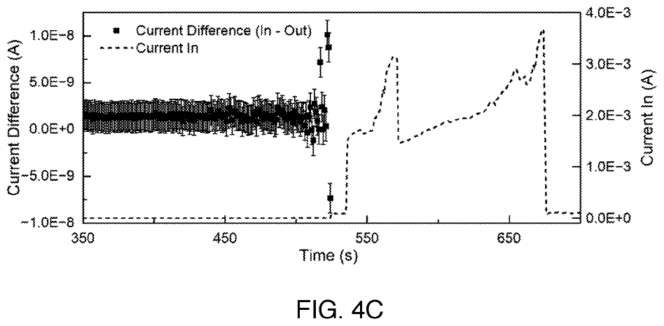

For charge accumulation, we suspect that protected chargeless topological states of electrons are formed. Charge storage of this kind would be expected to contradict Kirchhoff's law of conservation of charge. The measurements of FIG. 4A-C explore this possibility.

FIG. 4A shows current-voltage characteristics of an island-and-ring sample (inset) showing a schematic of additional incoming-current and outgoing-current measured simultaneously. FIG. 4B shows that the net incoming current (current difference or current imbalance) and the net charge accumulation show signs of anomalously large charge accumulation in the device. FIG. 4C shows a current imbalance with estimated total uncertainties that exhibits non-zero values followed by a significant current increase.

We electrically isolated the device from the platform it was resting on with an isolation layer and found that for low voltages, the current imbalance is zero, as predicted by Kirchhoff's law. However, as the voltage is increased, slightly before high current transports are observed, the difference between current in and out is measured to be in the hundreds of nano-Amps. This level of imbalance continues until the voltage is reduced and the high currents are no longer present. Then, the current imbalance observed returns to following the classical Kirchhoff's law of conservation of charge. In addition to the difference of current in and out at each point in time, we overlay the accumulated charge, integrating the difference. We find that the total integrated charge of one voltage sweep is ˜530 μC (˜129 C/cm² when normalized by area.) This charge accumulation is further confirmed in FIG. 4C by a non-zero current imbalance (plotted with uncertainty), which enables a significant device current (high incoming current), resembling a high-gain switching behavior.

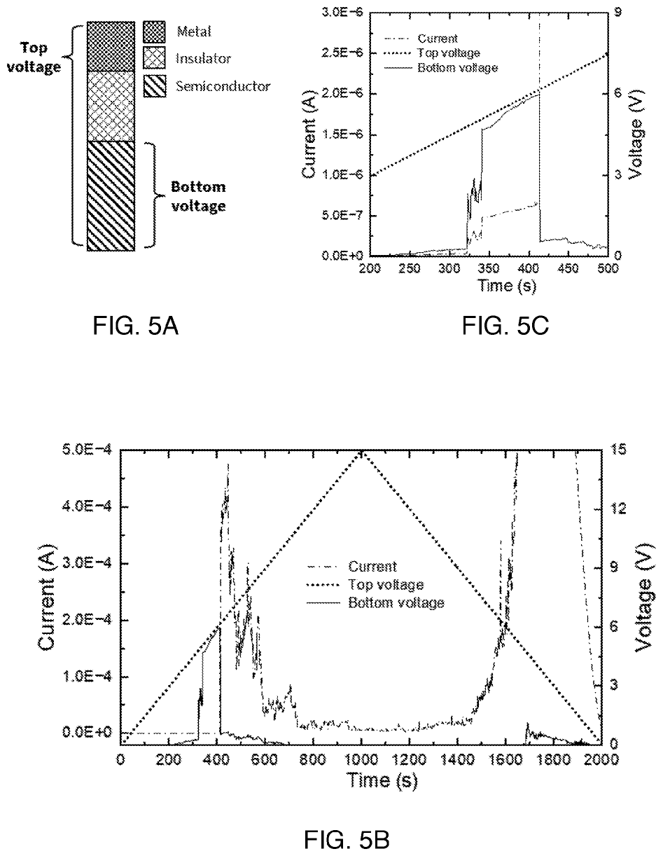

Further evidence of nonclassical storage and transport is seen in the results of FIGS. 5A-C. FIG. 5A is a schematic view of a MIS device (Metal-Insulator-Semiconductor) device, along with definitions of “top voltage” and “bottom voltage”. These two voltages were independently measured on the surface of the metal layer and on the surface of the semiconductor layer, respectively. FIG. 5B is a plot of current and top and bottom voltages as a function of time for a ramp of the top voltage. FIG. 5C is a magnified plot of the data of FIG. 5B for a time range of 200-500 seconds.

It is presently believed that this partial charge accumulation originating from the high current density behavior identified previously facilitates the lossless charge transport compatible with the Andreev reflection indicated by the tight-binding model. FIG. 5A shows a voltage drop measurement performed at the top and bottom electrodes. In a normal capacitive device, the bottom voltage should remain constant with a significant difference from the top voltage showing a voltage drop over the insulator layer. However, as shown in FIG. 5B and a zoom-in portion in FIG. 5C, there exists a region where the voltage drop over the insulator almost vanishes and persists during the high current.

### IV) Stability of the Topological States

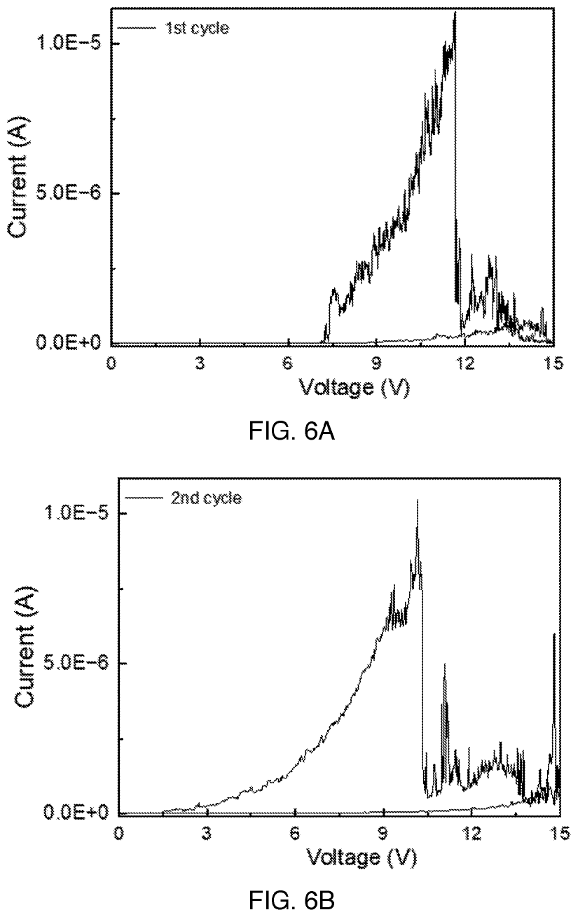

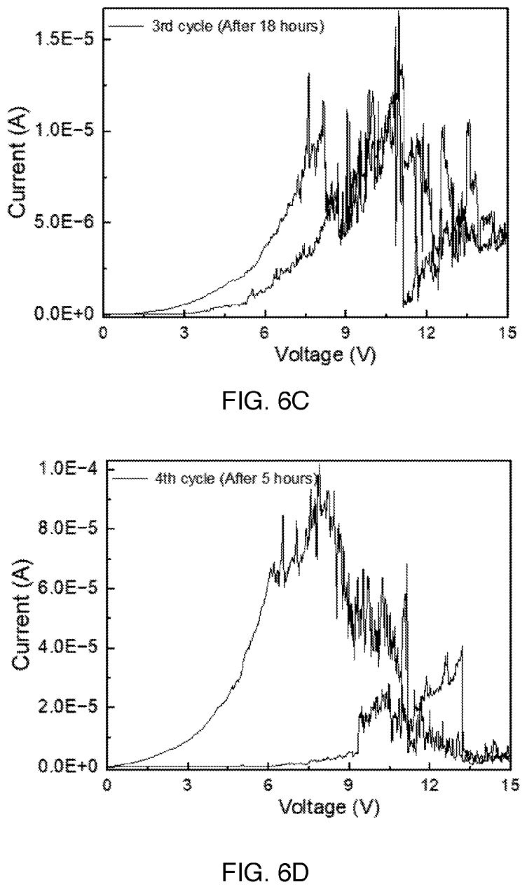

In addition to the aforementioned observation that the samples retain their physical integrity under high applied voltage and current response with the in-situ SEM experiment, they also exhibit the stability and repeatability (memory effect) of the formed topological states over a long period of time. FIGS. 6A-D show current-voltage characteristics of 4 repeated measurements. FIGS. 6A, 6B, 6C, and 6D are the first, second, third, and fourth cycles, respectively. The second cycle was done immediately after the first cycle was completed. The time intervals between the 2^{nd} and 3^{rd} cycles and the 3^{rd} and 4^{th} cycles are 18 hours and 5 hours, respectively. Apart from non-classical effects as described above, while the 3^{rd} and 4^{th} cycles have been spread out from the previous cycling for 18 hours and 5 hours, respectively, they still show the same behaviors with even higher current density indicating the stability of the topological states formed.

### V) Inverse Scaling of the Maximum Current Density and the Importance of the Semiconductor

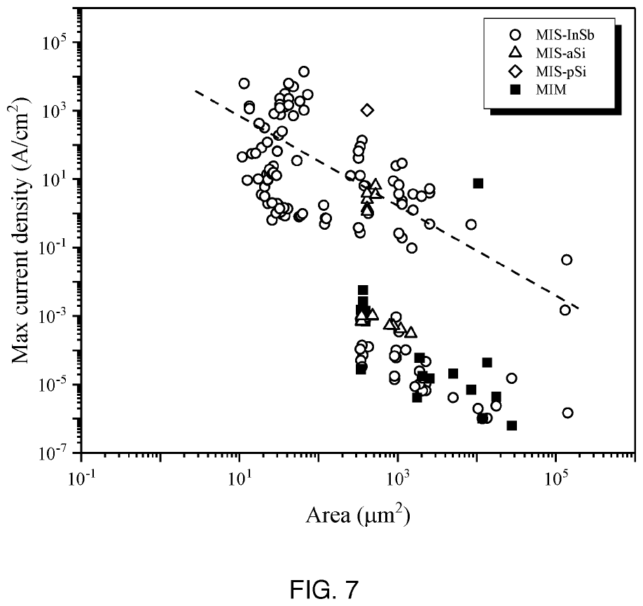

Repeated measurements on various samples with different patterns and fabrication architecture conform to the finding in earlier sections. These results are summarized on FIG. 7. More specifically, FIG. 7 shows scaling of maximum current density against the corresponding device area of devices with different semiconductor materials and without the semiconductor. The inverse dependence of maximum current density on the area shows a non-classical effect, departing from classical leakage or capacitive currents. Metal-insulator-semiconductor (MIS) capacitor shows a superior current density compared to the metal-insulator-metal (MIM). Besides the high current density in MIS-InSb, amorphous Si (MIS-aSi) and highly doped p-Si (MIS-pSi) show moderate to high current density levels.

An unusual feature of these results is an inverse dependence on area, as seen in FIG. 7—the smaller the area, the higher the maximum current density. This goes against leakage and geometric capacitive currents or any other classical behaviors. FIG. 7 also shows that the metal-insulator-semiconductor (MIS) capacitor exhibits a superior current density compared to the metal-insulator-metal (MIM) capacitor without a semiconductor layer. In fact, the currents seen in the MIM control structures tend to be at the lower limit our measurements are capable of detecting, so the apparent 1/area scaling of current density for the MIM data points on FIG. 7 is not significant. Among semiconductor materials tested in MIS capacitors, while InSb generally gives the highest current, amorphous Si and highly doped p-Si also show promising results with room for further improvement.

### VI) Exemplary Embodiments

Accordingly, one embodiment of the invention (Example 1) is a method of improving charge storage and/or charge transport in a semiconductor device, the method comprising:
forming a low-dimensional electron gas in a room temperature MIS (Metal/Insulator/Semiconductor) structure with an electrical bias, wherein the electrical bias includes an in-plane component in a plane of the low-dimensional dimensional electron gas, and wherein the electrical bias includes an out-of-plane component perpendicular to the plane of the low-dimensional electron gas;
wherein the room temperature MIS structure has topological states that are formed by application of the electrical bias followed by injection of charge carriers.

Here a low-dimensional electron gas is confined in at least one dimension, and can optionally be further confined partially or completely in another orthogonal dimension. Thus low-dimensional electron gases include 2D electron gases and 2D electron gases where the electrical biasing tends to partially or completely make the 2D electron gas 1D.

Suitable semiconductors for use in Example 1 include, but are not limited to: InSb (amorphous and crystalline), Si (amorphous and crystalline), InAs (crystalline), PbS (crystalline), and PbSe (crystalline).

Preferably, the semiconductor device in Example 1 provides charge storage at least ten times what would be expected from a classical capacitance of the semiconductor device. The classical capacitance of a charge storage device is the capacitance expected from its geometry and material composition. In a simple parallel plate configuration, this classical capacitance C is εA/d where A is the plate area, d is the plate separation and ε is the dielectric constant of the material between the plates. The charge Q on a capacitor is given by Q=CV, where V is the voltage on the capacitor. In embodiments of the invention, charge storage far higher than what would be classically expected is observed. In one example of a circular island geometry with 20 micron diameter, the classical capacitance (C) is ˜0.15 pF. At 30V (max V we ramped), the maximum charge that the classical capacitor can hold is as high as ˜4.5 pC. For the entire period of the charging (from 0V to 30 and back to 0V), this amounts to ˜135 pC. This is much lower compared to the results we saw from the charge storage measurement on our new charge storage device (also with 20 um diameter) of ˜530 uC (micro Coulomb).

Preferably, the semiconductor device in Example 1 provides charge release at least ten times what would be expected from a classical capacitance of the semiconductor device. Here the comparison to what would be expected from a classical capacitance of the semiconductor device is as described above in connection with charge storage.

Preferably, the semiconductor device in Example 1 provides current conduction at least ten times a charging or discharging current of a classical capacitance of the semiconductor device. The classical instantaneous current of a capacitor is calculated using the geometric capacitance and voltage ramp rate (i.e., I=C dV/dt). With the representative capacitor size that we use (circular island with 20 micron diameter), the capacitance C is ˜0.15 pF. With the voltage ramp rate of 10 mV/s, the classical capacitive current is ˜1.5 fA. This is much lower compared to the result we saw from the measurement having current at least in uA (micro Amp) level.

Preferably, the semiconductor device in Example 1 is operated without applying a magnetic field. As indicated above, this is in sharp contrast to Quantum Hall effect devices, where an applied magnetic field is required.

The room temperature MIS structure in Example 1 preferably includes two electrodes sandwiching the low-dimensional electron gas. In this case, the in-plane component of the electrical bias can be provided by a fringing electric field of the two electrodes.

The semiconductor device in Example 1 can be configured as two or more laterally concentric rings, where a lateral direction is in the plane of the low-dimensional electron gas. Fringing fields from the rings can be configured to promote formation of topological states. For example, as considered above, fringing fields from a central island and/or an outer ring can promote formation of topological states in a middle ring.

The topological states in Example 1 can persist in the semiconductor device after removal of the electrical bias.

Preferably the insulator in Example 1 is made of one or more layers of high-breakdown strength dielectric with a break-down strength higher than 0.5 V/nm). For example, the insulator can be an alumina/silica/alumina 3-layer stack. Suitable materials for such single-or multi-layer insulators include but are not limited to alumina, silica, and silicon nitride.

1. A method of improving charge storage and/or charge transport in a semiconductor device, the method comprising:
forming a low-dimensional electron gas in a room temperature MIS (Metal/Insulator/Semiconductor) structure with an electrical bias, wherein the electrical bias includes an in-plane component in a plane of the low-dimensional electron gas, and wherein the electrical bias includes an out-of-plane component perpendicular to the plane of the low-dimensional electron gas;
wherein the room temperature MIS structure has topological states that are formed by application of the electrical bias followed by injection of charge carriers.

2. The method of claim 1, wherein the semiconductor device provides charge storage at least ten times what would be expected from a classical capacitance of the semiconductor device.

3. The method of claim 1, wherein the semiconductor device provides current conduction at least ten times a charging or discharging current of a classical capacitance of the semiconductor device.

4. The method of claim 1, wherein the semiconductor device provides charge release at least ten times what would be expected from a classical capacitance of the semiconductor device.
